(19) United States
(12) Patent Application Publication
(10) Pub. No.: US 2025/0268067 A1
(43) Pub. Date: Aug. 21, 2025

(54) Display Device

(71) Applicant: LG Display Co., Ltd., Seoul (KR)

(72) Inventors: Sung Gon Hong, Paju-si (KR); Jong Chan Park, Paju-si (KR)

(21) Appl. No.: 18/925,678

(22) Filed: Oct. 24, 2024

(30) Foreign Application Priority Data
Feb. 15, 2024 (KR) 10-2024-0021552

(51) Int. Cl. H10K 59/80; H10K 59/40

(52) U.S. Cl. CPC H10K 59/873; H10K 59/40

(57) ABSTRACT

A display device may include a substrate having a display area and a non-display area including a bending area, an encapsulation layer disposed on the display area and the non-display area, an inner dam in contact with the encapsulation layer in the non-display area, a touch member disposed on the encapsulation layer and the inner dam and including a protective film, and an outer dam in contact with an end of the protective film of the touch member in the non-display area.

### CROSS-REFERENCE TO RELATED APPLICATION

This application claims priority to and the benefit of Republic of Korea Patent Application No. 10-2024-0021552, filed on Feb. 15, 2024, which is hereby incorporated by reference in its entirety.

### BACKGROUND

### Field

The present specification relates to a display device, and more particularly to a display device capable of improving reliability.

### Description of the Related Art

Display devices that display images on televisions TVs, monitors, smartphones, tablet PCs, and laptops are used in a variety of methods and forms.

The display devices include a display panel having a plurality of light-emitting elements or liquid crystals for implementing an image and a transistor for controlling the operation of each light-emitting element or liquid crystal, and display the image to be displayed by the plurality of light-emitting elements or liquid crystals as it is.

A light-emitting display device having self-emitting elements may be implemented thinner than a display device having a built-in light source, and do not require a separate light source, making it possible to bend the display device or implement the display device in various designs.

The field of the display devices that visually display electrical information signals is developing rapidly with the advent of information age, and research is continuing on the performance development and sustainability of the display devices, such as a narrow bezel, low power consumption, and ensuring reliability for various display devices.

### SUMMARY

The technical challenge of embodiments of the present specification is to provide a display device that is capable of effectively controlling the flow of a protective film by increasing a surface energy difference or surface resistivity.

The technical challenge of embodiments of the present specification is to provide a display device that is capable of improving reliability by reducing the stress concentration at the periphery of the bending area, thereby minimizing or at least reducing the occurrence of cracks.

The technical challenge of embodiments of the present specification is to provide a display device that is capable of preventing or reducing a waviness phenomenon in an optical member.

The technical challenge of embodiments of the present specification is to provide a display device that is capable of reducing manufacturing process cost by reducing product defects, reducing the manufacturing energy by shortening the manufacturing process time, and reducing the greenhouse gas by reducing the product defects.

In one embodiment, a display device comprises: a substrate including a display area where an image is displayed and a non-display area where the image is not displayed, the non-display area having a bending area where are portion of the substrate is bent; an encapsulation layer on the display area and the non-display area; an inner dam that is in contact with a portion of the encapsulation layer in the non-display area; a touch member configured to sense touch, the touch member including a protective film that is on the encapsulation layer and the inner dam; and an outer dam that is in contact with an end of the protective film of the touch member in the non-display area.

In one embodiment, a display device comprises: a substrate including a display area and a non-display area; a thin film transistor in the display area; a light emitting element in the display area, the light emitting element electrically connected to the thin film transistor; a first dam in the non-display area; an encapsulation layer over the light emitting element in the display area and extending to the non-display area, the encapsulation layer contacting the first dam in the non-display area; a touch member configured to sense touch of the display device, the touch member including a plurality of touch lines on the encapsulation layer and extend from the display area to the non-display area and a protective film that covers the plurality of touch lines in the display area and the non-display area; and a second dam that contacts the protective film in the non-display area without being covered by the encapsulation layer in the non-display area.

The display device of the present specification may effectively control the flow of the protective film of the touch member so that an optical member may be sufficiently supported, thereby improving the waviness defect of the optical member and thereby improving the display quality.

The display device according to the present specification may reduce the manufacturing process cost and shorten the manufacturing process time due to the reduced defect rate, and may also reduce the production energy.

In addition, the display device according to one embodiment of the present specification may reduce the generation of the greenhouse gas that may occur due to the manufacturing process by optimizing the process, such as not increasing the manufacturing process, thereby implementing ESG (Environment/Social/Governance).

### BRIEF DESCRIPTION OF THE DRAWINGS

The above and other objects, features, and advantages of the present specification will become more apparent to those of ordinary skill in the art by describing exemplary embodiments thereof in detail with reference to the attached drawings, in which:

FIG. 1 is a plan view of a display device according to one embodiment of the present disclosure;

FIG. 2 is one embodiment of a cross-sectional view taken along the line I-r of FIG. 1 according to one embodiment of the present disclosure;

FIG. 3 is a plan view of the display panel of FIG. 2, according to one embodiment;

FIG. 4 is a circuit diagram of the sub-pixel of FIG. 3, according to one embodiment;

FIG. 5 is an enlarged partial plan view of a portion A of FIG. 3 according to one embodiment;

FIG. 6 is a cross-sectional view in which an optical member is combined with the cross-section view taken along the line II-IP of FIG. 5 according to one embodiment;

FIG. 7 is an enlarged partial plan view of a portion B of FIG. 5, according to one embodiment;

FIG. 8 is an enlarged partial plan view of portion B of FIG. 5, according to another embodiment;

FIG. 9 is a cross-sectional view taken along the line III-III′ of FIG. 7 according to one embodiment; and

FIG. 10 is a cross-sectional view taken along the line IV-IV′ of FIG. 7 according to one embodiment.

### DETAILED DESCRIPTION

Hereinafter, embodiments will be described with reference to the drawings.

The same reference numerals refer to the same components. Also, in drawings, the thickness, ratio, and dimensions of the components may be exaggerated for an effective explanation of the technical content. The dimensions of the components shown in the drawings are to scale for illustrative purposes only and are not to scale with the actual components shown in the drawings.

Herein, when a component (or region, layer, portion, etc.) is referred to as being “on”, “connected”, or “coupled” to another component, it is intended to mean that it may be directly connected/combined with the other component, or that a third component may be interposed between them.

The term “and/or” includes any one or more combinations that the associated configurations may define.

Terms such as “first,” “second,” and the like may be used to describe various components, but the components are not limited by such terms. These terms are used for the sole purpose of distinguishing one component from another. For example, without departing from the scope of the present embodiments, a first component may be referred to as a second component, and similarly, a second component may be referred to as a first component. Singular expressions include plural expressions unless the context clearly indicates otherwise.

The terms “below,” “at the bottom,” “above,” “on the top,” and the like are used to describe the relationship of the configurations shown in the drawings. These terms are relative and are described with reference to the orientation shown in the drawings. For example, one or more other parts may be located between the two parts unless “immediately” or “directly” is used. The spatially relative terms “below,” “beneath,” “lower,” “above,” “upper,” and the like may be used to facilitate the description of the correlation between one element or component and another element or component, as shown in the drawings. The term spatially relative should be understood to include different orientations of the element in use or operation in addition to the orientations shown in the drawings. For example, an element described as “below” or “beneath” another element may be placed “above” another element if the elements shown in the drawings are reversed. Thus, the exemplary term “down” may include both down and up directions.

It should be understood that terms “include” or “have” are intended to specify the presence of features, numbers, steps, actions, components, parts, or combinations thereof described in the specification and not to exclude the presence or additional possibilities of one or more other features or numbers, steps, actions, components, parts, or combinations thereof.

Each of the features of the various embodiments described herein may be combined with one another, in part or in whole, and are technically capable of various interlocking and operating arrangements, and each embodiment may be practiced independently of or in conjunction with one another.

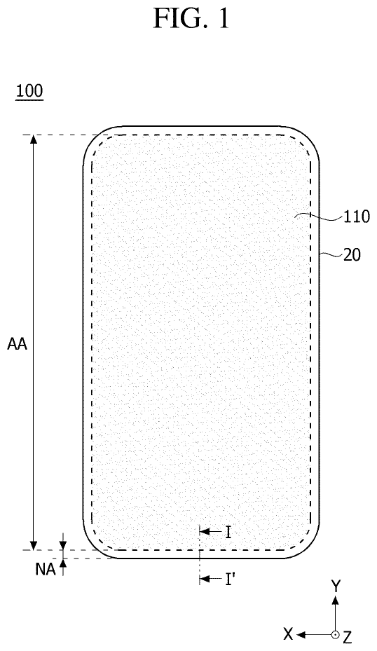

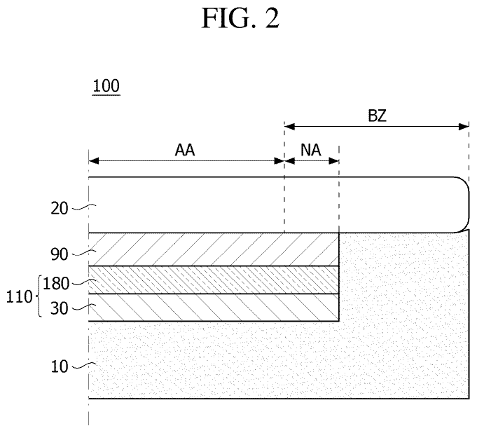

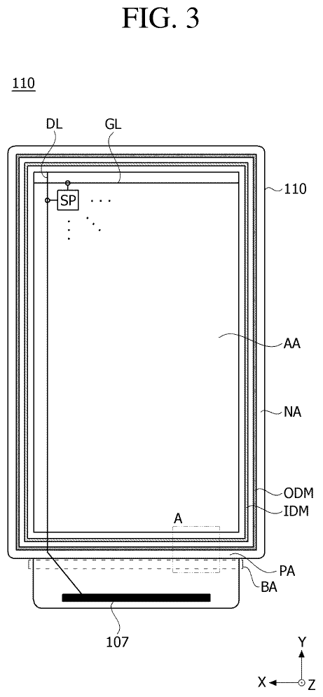

Hereinafter, a display device of the present specification will be described with reference to the accompanying drawings and embodiments as follows. FIG. 1 is a plan view of a display device according to one embodiment of the present disclosure, FIG. 2 is a cross-sectional view taken along the line I-I′ of FIG. 1 according to one embodiment, and FIG. 3 is a plan view of the display panel of FIG. 2, according to one embodiment.

Referring to FIGS. 1 and 2, a display device 100 according to an example of the present specification includes a display panel 110 including a display area AA and a non-display area NA, and an optical member 90 disposed on the display panel 110. The display device 100 may further include a bottom member 10 covering the bottom of the display panel 110 and a cover member 20 covering the top of the display panel 110. The bottom member 10 and the cover member 20 protect and support the display panel 110. The display panel 110 may include a panel 30 and a touch member 180 that is on the panel 30.

The display area AA of the display device 100 may be referred to as an area that displays an image, and the area other than the display area AA may be referred to as the non-display area NA or a bezel area BZ. The bezel area BZ may be referred to as an area in which the display area AA is obscured by the bottom member 10 and the cover member 20, which protect the display panel 110. The bezel area BZ may be the same size as the non-display area NA or larger in size than the non-display area NA.

The display area AA and the non-display area NA of the display device 100 may be equally applicable to the display panel 110. In FIG. 2, the non-display area NA and the bezel area BZ are illustrated based on the display panel 110 for ease of description, and the extent of the non-display area NA and the bezel area BZ is not limited to the illustration in FIG. 2.

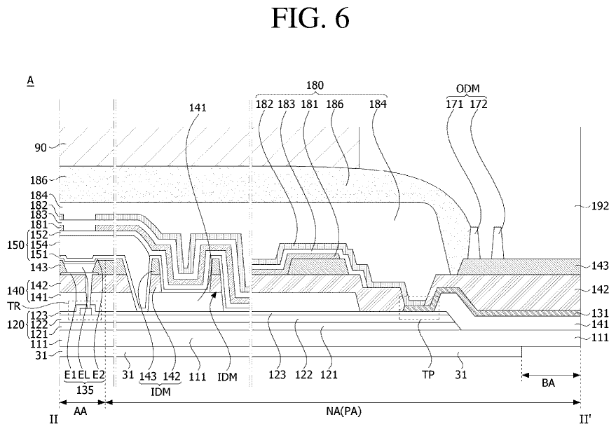

The bottom member 10 is disposed on the rear surface of the display panel 110 such that the lower portion of the display panel 110 maintains flat or level and provides additional rigidity. The bottom member 10 may be attached to the display panel 110 or to a structure on the rear surface of the display panel 110, such as a back plate 31 (see FIG. 6), using an adhesive or the like.

The bottom member 10 may be disposed to overlap the rear surface and the top and bottom, left and right sides of the display panel 110. The bottom member 10 may be rigid, may have a flat surface, and may include a metallic material. The bottom member 10 may include a metallic material such as SUS (Steel Use Stainless). The bottom member 10 may be a metal thin film or a metal plate.

The bottom member 10 including a metallic material may minimize, reduce, or prevent or reduce the occurrence of electromagnetic interference (EMI) of the display panel 110 and malfunction of the light-emitting element due to noise from batteries or semiconductor chips disposed on the rear surface of the bottom member 10 and attached to the display panel 110. The bottom member 10, which includes a metallic material, may also have a heat dissipation effect to dissipate heat and may function to protect the ground and the rear surface. The rigid bottom member 10 or the bottom member 10 made of a metallic material may protect the display panel 110 from external forces by increasing or reinforcing the rigidity.

The bottom member 10 may be disposed in a structure that overlaps or wraps around at least a portion of the side surfaces of the touch member 180 on the top and bottom, left and right side surfaces of the display device 100. The bottom member 10 may be disposed in a structure that is combined with the cover member 20 at a side portion of the display panel 110.

The cover member 20 may be disposed on the upper portion of the display panel 110 to cover the front surface of the display panel 110, thereby protecting the display panel 110 from external impact. The edge portion of the cover member 20 may have a curvature portion or a curved surface that can be bent in the rear surface direction (−Z axis direction) of the display device 100. This allows the cover member 20 to be arranged to cover even the side areas of the display panel 110 disposed in the rear surface of the cover member 20, thereby protecting the display panel 110 from external impacts not only from the front surface of the display device 100, but also from the side surfaces of the display device 100.

The cover member 20 may be formed of a transparent material so as to overlap the area displaying the image. For example, the cover member 20 may be made of, but is not limited to, a transparent plastic material, a tempered glass of a transparent glass material, a tempered plastic, or the like capable of transmitting an image.

The display area AA and the non-display area NA may be applied to the cover member 20 in the same manner. An area through which an image is transmitted in the cover member 20 may be the display area AA. An area in the cover member 20 that surrounds the display area AA and through which an image is not transmitted may be a bezel area BZ including the non-display area NA.

The cover member 20 may be attached to the display panel 110 or to a structure that is disposed between the display panel 110 and the cover member 20. In one embodiment, the cover member 20 may be combined with the optical member 90 on the display panel 110.

The optical member 90 may be attached to an upper portion of the display panel 110 and may prevent or at least reduce reflection of external light to improve outdoor visibility and contrast ratio of the image displayed on the display panel 110. The optical member 90 may be disposed on the display area AA of the display panel 110 and may extend to the non-display area NA.

The optical member 90 may include a polarizer and a protective film protecting the polarizer. The optical member 90 may be configured in a form in which an adhesive material is disposed on the top surface and the rear surface of the polarizer, or it may be disposed in a form in which a polarizing material having flexibility and adhesion is coated on the display panel 110.

Referring to FIG. 3, the display panel 110 includes the panel 30 and the touch member 180 disposed on the panel 30. The panel 30 may include the display area AA and the non-display area NA having a bending area BA.

A plurality of sub-pixels SP may be disposed in the display area AA of the panel 30, and an image may be displayed using the plurality of sub-pixels SP. An area in which the plurality of sub-pixels SP are disposed may be a display area AA, and an area other than the display area AA may be a non-display area NA.

The non-display area NA may be an edge area surrounding the display area AA that displays an image. The non-display area NA is disposed along the perimeter of the display area AA, and the non-display area NA, including the bending area BA, may be a pad area PA.

The pad area PA may be an area in which structures for receiving external signals are disposed, and in which, for example, a drive integrated circuit (IC) 107 such as a data driver IC is disposed.

In the pad area PA, the bending area BA may be located in an area between the drive integrated circuit 107 and the display area AA. In at least one of the left and right regions of the panel 30 other than the pad area PA of the non-display area NA, at least one driver for driving a plurality of sub-pixels SP may be disposed. The driver may be a Gate-In-Panel (GIP). Various additional elements for driving pixels in the display area AA may also be disposed in the non-display area NA.

The non-display area NA may have an inner dam IDM and an outer dam ODM surrounding the display area AA. The outer dam ODM is spaced apart from the inner dam IDM and is located on the outside of the inner dam IDM. As shown in FIG. 3, the inner dam IDM is between the display area AA and the outer dam ODM in a plan view of the display panel 110. Thus, the outer dam ODM is farther from the display area AA than the inner dam IDM. A detailed description of the inner dam IDM and the outer dam ODM will be described later.

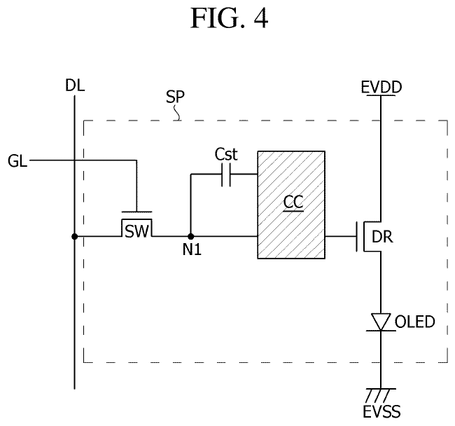

A plurality of sub-pixels SP in the display area AA of the panel 30 are arranged, and at least one sub-pixel SP may include a switching transistor SW, a driving transistor DR, a capacitor Cst, a compensation circuit CC, and a light-emitting element (OLED)135 (see FIG. 6), as shown in FIG. 4.

A first electrode (e.g., a drain electrode) of the switching transistor SW is electrically connected to a data line DL, and a second electrode (e.g., a source electrode) of the switching transistor SW is electrically connected to a first node N1. A gate electrode of the switching transistor SW is electrically connected to a gate line GL. The switching transistor SW transmits the data signal supplied through the data line DL to the first node N1 in response to a scan signal supplied through the gate line GL.

The capacitor Cst is electrically connected to the first node N1 to charge a voltage applied to the first node N1.

A first electrode (e.g., drain electrode) of the driving transistor DR receives a high potential driving voltage EVDD, and a second electrode (e.g., source electrode) of the driving transistor DR is electrically connected to a first electrode (e.g., anode electrode) of the light-emitting element OLED. The driving transistor DR may control the amount of driving current flowing to the light-emitting element OLED in response to a voltage applied to the gate electrode of the driving transistor DR.

A semiconductor layer of the switching transistor SW and/or the driving transistor DR may include silicon, such as amorphous silicon (a-Si), polycrystalline silicon (poly-Si), or low-temperature polycrystalline silicon (poly-Si), or may include an oxide, such as indium-gallium-zinc-oxide (IGZO).

The light-emitting element OLED output light corresponding to the driving current. The light-emitting element OLED may output light corresponding to any one of the following colors: red, green, blue, and white.

The light-emitting element OLED may include an anode electrode, a light emission layer disposed on the anode electrode, and a cathode electrode that supplies a common voltage. The light emission layer may be implemented to emit light of the same color, such as white light, for each pixel, or may be implemented to emit different colors, such as red, green, or blue light, for each sub-pixel SP.

The light-emitting element OLED may be a top-emission type diode or a bottom-emission type diode.

The compensation circuit CC may be provided in the sub-pixel SP to compensate for the threshold voltage of the driving transistor DR. The compensation circuit CC may include one or more transistors and capacitors, and may be configured in a variety of ways depending on the compensation method. The sub-pixel SP containing the compensation circuit CC may have various structures, such as 3T1C, 4T2C, 5T2C, 6T1C, 6T2C, 7T1C, and 7T2C, etc.

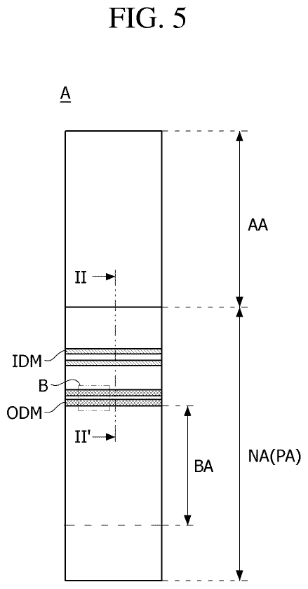

FIG. 5 is an enlarged partial plan view of an area D of FIG. 3 according to one embodiment, and FIG. 6 is a cross-sectional view in which the optical member 90 is combined with the cross-section view taken along the line I-If of FIG. 5 according to one embodiment. Referring to FIGS. 5 and 6, the panel 30 includes a substrate 111. An area on the substrate 111 may be divided into a display area AA and a non-display area NA. The display area AA and the non-display area NA on the substrate 111 correspond to the display area AA and the non-display area NA on the display panel 110. Among the non-display areas NA, the non-display area NA having the pad area PA may include the bending area BA. The outer dam ODM may be disposed in the non-display area NA adjacent to the bending area BA, and the inner dam IDM may be disposed on the substrate 111 in the non-display area NA between the outer dam ODM and the display area AA.

The substrate 111 serves to support and protect the components of the display device 100 that are disposed on top of the substrate 111.

The substrate 111 may be formed of a plastic material that has flexible property. The substrate 111 may be formed by including a polyimide, and may include a flexible, thin-thickness glass material.

The substrate 111 may independently include a support substrate, such as polyethylene terephthalate (PET), or a polyimide film. The substrate 111 may include an adhesive material, such as a pressure sensitive adhesive (PSA) for bonding the PET and polyimide film. The adhesive material may be applied in the form of a film.

The substrate 111 may have a structure in which two layers including the above-described materials are stacked with an intermediate layer (not shown) interposed therebetween.

Referring to FIG. 6, a number of insulating films 120 may be stacked and disposed on the display area AA and the non-display area NA of the substrate 111. The insulating film 120 may include a first insulating film 121, a second insulating film 122, and a third insulating film 123.

The first insulating film 121 is disposed on the display area AA and the non-display area NA on the substrate 111. The first insulating film 121 may be referred to as a buffer film and may function in the same manner as any buffer film known in the art. The first insulating film 121 may be disposed on the substrate 111 to protect the structures on the substrate 111 that are vulnerable to moisture from moisture penetration through the substrate 111 and to planarize the surface of the substrate 111.

The first insulating film 121 may be disposed on the bending area BA. The first insulating film 121 may be disposed so as to overlap the inner dam IDM and the outer dam ODM that are disposed in the outer portion of the substrate 111. The first insulating film 121 may be disposed up to an edge portion of the substrate 111 to prevent moisture from penetrating from the edge of the substrate 111.

The first insulating film 121 may be a single inorganic film or may have a structure in which a plurality of inorganic films are stacked. For example, the first insulating film 121 may include one or more inorganic films selected from a silicon oxide film (SiOx), a silicon nitride film (SiNx), and a silicon oxynitride film (SiOxNy), or may include, for example, a multilayer film in which the above-described inorganic films are stacked.

A transistor TR may be disposed on the upper portion of the substrate 111 and may be the switching transistor SW or the driving transistor DR as described in FIG. 4. The transistor TR may include a gate electrode, a source electrode, a drain electrode, and an active layer. The transistor TR may be disposed on the first insulating film 121.

The gate electrode serves to turn-on or turn-off the transistor TR based on an electrical signal supplied externally through the gate line GL or the data line DL and may be composed of a single or a multilayer of a conductive metal such as, but not limited to, copper (Cu), aluminum (Al), molybdenum (Mo), chrome (Cr), gold (Au), titanium (Ti), nickel (Ni), and neodymium (Nd), or alloys thereof.

The source electrode and the drain electrode may be composed of a single layer or a multilayer of a metallic material or an alloy thereof, including, but not limited to, copper (Cu), aluminum (Al), molybdenum (Mo), chrome (Cr), gold (Au), titanium (Ti), nickel (Ni), and neodymium (Nd), which are conductive metals.

The active layer may include a semiconductor material. The semiconductor material may be composed of a silicon-based semiconductor material or an oxide-based semiconductor material.

For ease of explanation, although the drawing illustrates the transistor TR connected to a light-emitting element 135 as an example among the various transistors TR constituting the display device 100, the same structure may be applied to other switching transistors SW and driving transistors DR and is not limited to the transistor TR connected to the light-emitting element 135. The transistor TR disposed in the display area AA may be a transistor TR including a silicon-based semiconductor material or a transistor TR including an oxide-based semiconductor material, depending on its function. Transistors TR including different semiconductor materials may be employed within a single sub-pixel SP.

The second insulating film 122 is disposed on the first insulating film 121. The second insulating film 122 may be disposed in the display area AA to separate the transistors TR including different semiconductor materials or to prevent a short circuit between their electrodes.

The second insulating film 122 may be disposed to extend to the non-display area NA and to overlap the inner dam IDM in the non-display area NA. The second insulating film 122 may include an inorganic film, such as a silicon oxide film (SiOx), a silicon nitride film (SiNx), or a multilayer film in which the above-described inorganic films are stacked.

The third insulating film 123 is disposed on the second insulating film 122. The third insulating film 123 may be disposed in the display area AA to insulate between the electrodes constituting the transistor TR on the substrate 111 or to insulate the electrodes and the active layer. The third insulating film 123 may be referred to as an interlayer insulating film and may function in the same manner as any interlayer insulating film known in the art.

The third insulating film 123 may be disposed to extend to the non-display area NA and to overlap the inner dam IDM in the outer portion of the non-display area NA. The third insulating film 123 may include an inorganic material. The inorganic material may include, for example, one or more inorganic films of silicon oxide (SiOx), silicon nitride (SiNx), silicon oxynitride (SiOxNy), or a multilayer film in which the above-described inorganic films are stacked.

A driving circuit part, at least one signal line and power line may be disposed on the substrate 111 of the non-display area NA, and a description of these will be omitted in the present specification.

The organic film 140 may be disposed on the transistor TR to protect the transistor TR and mitigate a step difference caused by the transistor TR. The organic film 140 may be disposed between the structures of the transistor TR and the light-emitting element 135 or the elements to reduce the parasitic capacitance generated between the transistor TR and the light-emitting element 135. The organic film 140 may be disposed on the insulating film 120 to provide a planarized surface.

The organic film 140 may be a film in which a film made of an organic material is formed of a single layer or a multilayer. The organic film 140 may include a first organic film 141 and a second organic film 142 on the first organic film 141.

The first organic film 141 covers the transistor TR in the display area AA to planarize the upper surface of the transistor TR, and planarize the upper surface of the non-display area NA.

The first organic film 141 may be disposed to extend up to the non-display area NA. The first organic film 141 may be disposed to overlap the inner dam IDM and outer dam ODM of the non-display area NA. The first organic film 141 may be disposed to overlap the bending area BA.

The first organic film 141 may include a contact hole in the non-display area NA for supplying signals or the like to lines or electrodes on the display area AA. For example, the first organic film 141 may have a contact hole that exposes a connection wire 131 disposed in the non-display area NA to supply signals to a first touch line 181 and a second touch line 182 that constitute the touch member 180 on the display area AA.

The first organic film 141 may include an inorganic material. The organic material may include one or more materials of acrylic resin, phenolic resin, polyimide resin, unsaturated polyester resin, polyamide resin, benzocyclobutene, polyphenylene resin, and polyphenylene sulfide resin.

The first organic film 141 may be disposed as a composite stack of an inorganic insulating material film and an organic insulating material film.

The second organic film 142 may be disposed on the first organic film 141.

The second organic film 142 covers the transistor TR and the first organic film 141 in the display area AA and the non-display area NA to planarize their upper surface. The second organic film 142 is disposed on the first organic film 141 in the display area AA to extend to the non-display area NA.

The second organic film 142 may constitute a portion of the inner dam IDM in the non-display area NA, and may be disposed under the outer dam ODM such that it overlaps the outer dam ODM. The second organic film 142 may be disposed to overlap the bending area BA. Thus, a portion of the inner dam IDM includes a same material as the second organic film 142.

The second organic film 142 may be disposed to overlap the contact hole of the first organic film 141 in the non-display area NA. The second organic film 142 may have a contact hole of the second organic film 142 in the area where the layer disposed under the first organic film 141 is exposed by the first organic film 141.

For example, the second organic film 142 may have a contact hole of the second organic film 142 that exposes a connection wire 131 disposed in the non-display area NA to supply signals to a first touch line 181 and a second touch line 182 that constitute the touch member 180 on the display area AA. The first touch line 181 and the second touch line 182 constituting the touch member 180 may be connected with the connection wire 131 through the contact hole of the second organic film 142 in the non-display area NA.

The second organic film 142 may be disposed on the planarized upper surface of the first organic film 141 in the non-displayed area NA so as to constitute a portion of the inner dam IDM. A width of the bottom surface of the second organic film 142, which constitutes the inner dam IDM, is smaller than a width of the top surface of the first organic film 141.

The second organic film 142 may include an inorganic material. The organic material may include one or more materials of acrylic resin, phenolic resin, polyimide resin, unsaturated polyester resin, polyamide resin, benzocyclobutene, polyphenylene resin, and polyphenylene sulfide resin.

The second organic film 142 may be disposed as a composite stack of an inorganic insulating material film and an organic insulating material film.

In addition to the insulating film 120 described above, organic films or inorganic films having various functions may be further disposed between the substrate 111 and the organic film 140.

The light-emitting element 135 is disposed on the organic film 140 of the display area AA. The light-emitting element 135 may be electrically connected to the transistor TR through the organic film 140. The light-emitting element 135 includes a first electrode E1, a light emission layer EL on the first electrode E1, and a second electrode E2 on the light emission layer EL.

The first electrode E1 may function as an anode. The first electrode E1 may be connected to the transistor TR by passing through the organic film 140.

The first electrode E1 may include a metallic material having high reflectivity. For example, the first electrode E1 may be formed of a multilayer structure, such as a stacked structure (Ti/Al/Ti) of aluminum (Al) and titanium (Ti), a stacked structure (ITO/Al/ITO) of aluminum (Al) and ITO, and a stacked structure (ITO/APC/ITO) of an APC (Ag/Pd/Cu) alloy, and an APC alloy and ITO, or a stacked structure (Ag/MoTI) of silver (Ag) and molybdenum/titanium alloy, or it may include a single layer structure made of any one material or an alloy of two or more materials selected from silver (Ag), aluminum (Al), molybdenum (Mo), gold (Au), magnesium (Mg), calcium (Ca), or barium (Ba). The first electrode E1 may be referred to as a reflective electrode.

The light emission layer EL is provided on the first electrode E1. The light emission layer EL may include a hole injection layer, a hole transport layer, an organic light emission layer, an electron transport layer, and an electron injection layer.

When a voltage is applied to the first electrode E1 and the second electrode E2, holes and electrons are transferred to the organic light emission layer through the hole injection layer and the hole transport layer and the electron injection layer and the electron transport layer, respectively, and they combine with each other in the organic light emission layer to emit light.

Although the drawing shows that the light emission layer EL is disposed in an opening area, the hole injection layer, the hole transport layer, the electron transport layer, and the electron injection layer constituting the light-emission layer EL are commonly disposed in the front of the display area AA.

The light emission layer EL may include a red light emission layer that emits red light, a green light emission layer that emits green light, and a blue light emission layer that emits blue light. The red light emission layer, the green light emission layer, and the blue light emission layer may be disposed on the first electrode E1 for each sub-pixel SP. The red light emission layer may be patterned and disposed in the red sub-pixel, the green light emission layer may be patterned and disposed in the green sub-pixel, and the blue light emission layer may be patterned and disposed in the blue sub-pixel, but is not necessarily limited thereto, and at least two or more organic light emission layers among the red light emission layer, the green light emission layer, and the blue light emission layer may be stacked and disposed in one sub-pixel SP.

The light emission layer EL may be a white light emission layer that emits white light. In this case, the organic light emission layer of the light emission layer EL may be a common layer commonly disposed rather than patterned in the sub-pixels SP.

As previously described, the light emission layer EL may be arranged in a tandem structure of two or more stacks. In this case, each of the light-emitting elements 135 may include a charge generating layer disposed between the stacks. The charge generating layer may be a common layer disposed on the front surface of the display area AA.

The second electrode E2 is provided on the light emission layer EL. The second electrode E2 may function as a cathode. The second electrode E2 may be disposed not only in the emission area of the sub-pixel SP but also in the whole area of the display area AA. The second electrode E2 may be disposed in a patterned manner if the display area AA is functionally divided.

The second electrode E2 may be a common layer that is commonly disposed in the sub-pixels SP and applies the same voltage. To this end, the second electrode E2 may be disposed in the display area AA to extend up to a portion of the non-display area NA.

The second electrode E2 may be a light-transmissive electrode. The second electrode E2 may include a transparent conductive material (TCO, Transparent Conductive Material), such as ITO or IZO, which may transmit light, or a semi-transmissive conductive material, such as magnesium (Mg), silver (Ag), or an alloy of magnesium (Mg) and silver (Ag). When the second electrode E2 includes a semi-transmissive conductive material, the light emission efficiency may be increased by the micro-cavity.

In the above, the top-emission type has been described as an example of the light-emitting element 135. However, the light-emitting element 135 of the present specification is not limited thereto and may be of the bottom-emission type in which light emitted from the light emission layer EL is emitted toward the substrate 111. In this case, the first electrode E1 may be composed of a transparent or translucent electrode material, and the second electrode E2 may be composed of a reflective electrode material. The materials described above may be applied as the transparent and translucent electrode material and the reflective electrode material.

A third organic film 143 may be disposed on the second organic film 142 to cover an end of the first electrode E1 of the light-emitting element 135.

The third organic film 143 may be referred to as a bank defining the emission area of the light emitting element 135. The third organic film 143 is disposed to ensure that the first electrodes E1 between adjacent sub-pixels SP are electrically insulated therebetween while opening the first electrode E1 of the emission area for each sub-pixel. The third organic film 143 may be disposed to function as a spacer as well as a bank by using a halftone mask.

The third organic film 143 may be disposed in the display area AA to extend up to a portion of the non-display area NA. The third organic film 143 may be disposed in a patterned manner in the non-display area NA depending on the function of the area.

The third organic film 143 may be disposed on the second organic film 142 in the non-display area NA to constitute a portion of the inner dam IDM. That is, a portion of the inner dam IDM is made of a same material as the third organic film 143. The third organic film 143 may be disposed under the outer dam ODM to overlap the outer dam ODM. The third organic film 143 may be disposed on the second organic film 142 of the bending area BA to overlap the bending area BA.

The third organic film 143 may include one organic material selected from polyimide resin, acrylic resin, epoxy resin, phenolic resin, and polyamide resin.

An encapsulation layer 150 is disposed on the light-emitting element 135. The encapsulation layer 150 is disposed on the display area AA and the non-display area NA. The encapsulation layer 150 may cover the display area AA and the non-display area NA to prevent or at least reduce oxygen or moisture from penetrating into structures on the substrate 111, such as the light-emitting element 135 and the transistor TR. Other layers, such as a capping layer, may also be interposed between the encapsulation layer 150 and the second electrode E2 as desired.

The encapsulation layer 150 may be composed of a plurality of layers. The encapsulation layer 150 may be made of a structure in which organic films and inorganic films are alternately stacked. The encapsulation layer 150 according to one embodiment of the present specification may include a first encapsulation layer 151, a second encapsulation layer 152, and an organic encapsulation layer 154 disposed between the first encapsulation layer 151 and the second encapsulation layer 152. The first and second encapsulation layers 151 and 152 may be inorganic encapsulation films. The first encapsulation layer 151 may be disposed adjacent to the light-emitting element 135, and the second encapsulation layer 152 may be disposed at the uppermost end of the encapsulation layer 150.

The first encapsulation layer 151 constituting the encapsulation layer 150 is disposed in the display area AA and the non-display area NA on the substrate 111. The first encapsulation layer 151 may be disposed on the upper front surface of the transistor TR and the light-emitting element 135 of the display area AA. The first encapsulation layer 151 may completely cover the light-emitting element 135 to seal the light-emitting element 135.

The first encapsulation layer 151 may be disposed to extend up to a portion of the non-display area NA. The first encapsulation layer 151 may be disposed to overlap the inner dam IDM in the non-display area NA. The first encapsulation layer 151 may cover the inner dam IDM and may be disposed to extend toward the bending area BA. The first encapsulation layer 151 does not overlap (e.g., is non-overlapping) the outer dam ODM adjacent to the bending area BA and is not disposed in the bending area BA.

The first encapsulation layer 151 may be made of an inorganic insulating material. For example, the first encapsulation layer 151 may include silicon oxide, silicon nitride, and/or silicon oxynitride, which are inorganic insulating materials.

An organic encapsulation layer 154 is disposed on the first encapsulation layer 151, and the organic encapsulation layer 154 functions to planarize the upper surface so as to minimize or at least reduce cracking that may occur due to step coverage by the structures under the organic encapsulation layer 154.

The organic encapsulation layer 154 may include one or more organic materials selected from the group consisting of polyethylene terephthalate, polyethylene naphthalate, polycarbonate, polyimide, polyethylene sulfonate, polyoxymethylene, polyarylate, and hexamethyldisiloxane.

The organic encapsulation layer 154 may be made of an organic material and it may flow in a liquid state during the process, and the inner dam IDM is disposed in the non-display area NA at the outer portion of the display area AA to control the flow of the organic encapsulation layer 154. The inner dam IDM prevents the organic encapsulation layer 154 from extending past the inner dam IDM.

The inner dam IDM may be disposed in the non-display area NA in such a way that it surrounds the display area AA. The inner dam IDM is in contact with the encapsulation layer 150 in the non-display area NA. One or more inner dams IDM may be disposed or a number of inner dams IDM may be disposed to be spaced apart from each other, and the first organic film 141 may be disposed to be exposed in a space where a number of inner dams IDM are spaced apart from each other. When there are a plurality of internal dams IDM, a portion of the organic encapsulation layer 154 may be disposed between the plurality of internal dams IDM.

The inner dam IDM may be disposed in an embossed structure on the substrate 111, and may be disposed to include a portion of the second organic film 142 on the first organic film 141 in the non-display area NA and a portion of the third organic film 143 on the portion of the second organic film 142 in the non-display area NA.

The first encapsulation layer 151 and the second encapsulation layer 152 may be combined on the inside surface of the inner dam IDM or on the upper portion of the inner dam IDM to trap the organic encapsulation layer 154 disposed between the first encapsulation layer 151 and the second encapsulation layer 152 inside the inner dam IDM. The combined structure of the first encapsulation layer 151 and the second encapsulation layer 152, or the second encapsulation layer 152, may be disposed to extend onto the substrate 111 at the outer portion of the inner dam IDM along the outside of the inner dam IDM.

As used herein, the inside refers to the side facing the display area AA with respect to the corresponding structure, and the outside refers to the side facing the edge of the display panel 110 with respect to the corresponding structure.

In one example, the combined structure of the first encapsulation layer 151 and the second encapsulation layer 152 or the second encapsulation layer 152 may be disposed to extend toward the bending area BA, and the combined structure of the first encapsulation layer 151 and the second encapsulation layer 152 or the second encapsulation layer 152 does not overlap the outer dam DOM adjacent to the bending area BA and is not disposed in the bending area BA.

Because the flow of the organic encapsulation layer 154 is controlled by the inner dam IDM, the organic encapsulation layer 154 is in contact with the inner dam IDM, but does not contact the outer dam ODM.

The second encapsulation layer 152 may be disposed on the organic encapsulation layer 154.

The second encapsulation layer 152 may be in contact with or combined with the lower first encapsulation layer 151 in an area where the inner dam IDM is disposed, and may be disposed to cover the organic encapsulation layer 154. The second encapsulation layer 152 may completely cover the organic encapsulation layer 154 disposed in the display area AA and the non-display area NA. The second encapsulation layer 152 is combined with the first encapsulation layer 151 in an area where the inner dam IDM is disposed, so that the organic encapsulation layer 154 may not be exposed to the outside.

The second encapsulation layer 152 may disposed to extend up to the end of the substrate 111, but not disposed in the bending area BA. The second encapsulation layer 152 may be disposed up to the inside of the bending area BA in the non-display area NA having the pad area PA, and may be disposed up to the end of the substrate 111 in the other non-display area NA.

In this way, the lower first encapsulation layer 151 and the uppermost second encapsulation layer 152 constituting the encapsulation layer 150 contact each other on the side surface of the inner dam IDM, and the organic encapsulation layer 154 is trapped inside the inner dam IDM, which may prevent moisture or oxygen from penetrating from the outside and reduce the occurrence of cracking due to moisture penetration, thereby reducing the deformation of the panel 30.

The second encapsulation layer 152 may be made of an inorganic insulating material. For example, the second encapsulation layer 152 may include silicon oxide, silicon nitride, and/or silicon oxynitride, which are inorganic insulating materials.

A touch member 180 is disposed on the encapsulation layer 150. The touch member 180 is configured to sense touch of the display device. The touch member 180 is disposed between the optical member 90 and the panel 30, and the touch member 180 may be disposed directly on the encapsulation layer 150. In this case, as shown in FIG. 2, the optical member 90 is disposed on the upper portion of the touch member 180. The encapsulation layer 150 may be disposed on the inner dam IDM and the touch member 180 may be disposed on the encapsulation layer 150 to overlap the inner dam IDM. The touch member 180 may be disposed on the inner dam IDM with the encapsulation layer 150 therebetween.

The touch member 180 is disposed in a position corresponding to the display area AA of the panel 30, and the touch member 180 may be disposed to extend past the encapsulation layer 150 and the inner dam IDM in the non-display area NA. The touch member 180 is disposed to correspond to the panel 30 until before the bending area BA.

The touch member 180 includes a first touch line 181, a second touch line 182, a touch planarization film 184, and a protective film 186. The touch member 180 further includes a touch insulation film 183 disposed between the first touch line 181 and the second touch line 182 to insulate the touch insulating film 183. In one embodiment, the first and second touch lines each include a respective plurality of touch electrodes in the display area AA and touch routing lines in the non-display area NA that are connected to the touch electrodes.

The first touch line 181 is disposed on the encapsulation layer 150. The first touch line 181 may be disposed on the second encapsulation layer 152 to correspond to the display area AA and the non-display area NA. Although only briefly illustrated, the first touch line 181 disposed to correspond to the display area AA and the non-display area NA may be formed with a single conductive film extending therefrom, or may be formed with multiple conductive films disposed and connected in different layers.

The first touch line 181 may be disposed in a non-emission area other than the emission area in the display area AA, which is opened by the third organic film 143, to prevent the luminance and light transmittance of the emission area from deteriorating.

The first touch line 181 may be disposed in a mesh shape in a non-emission area. The inside of the mesh shape may be a rhombus or a rectangle. The emission area may correspond to the sub-pixel SP. The first touch line 181 is disposed to overlap the third organic film 143 in the non-emitting area in the display area AA.

The first touch line 181 may cover the inner dam IDM in the non-display area NA and may be disposed up to an area adjacent to the outer dam ODM that is past (e.g., outside) the inner dam IDM.

The first touch line 181 may be disposed using an opaque conductive material having a low material resistivity. The first touch line 181 may be disposed as a single layer or a multilayer made of any one of molybdenum (Mo), copper (Cu), titanium (Ti), aluminum (Al) chrome (Cr), gold (Au), nickel (Ni), neodymium (Nd), tungsten (W), gold (Au), and transparent conductive oxide (TCO), or an alloy thereof.

The second touch line 182 may be disposed on the first touch line 181 and insulated from the first touch line 181 with the touch insulating film 183 interposed therebetween. Although not shown in the drawings, in another embodiment, the second touch line 182 may be disposed on the same layer as the first touch line 181 while being electrically insulated from the first touch line 181. When the first touch line 181 and the second touch line 182 are disposed on the same layer, the first touch line 181 and the second touch line 182 may each be disposed in a block shape.

The second touch line 182 may be disposed on the second encapsulation layer 152 to correspond to the display area AA and the non-display area NA. Although only briefly illustrated, the second touch line 182 disposed to correspond to the display area AA and the non-display area NA may be formed with a single conductive film extending therefrom, or may be formed with multiple conductive films disposed and connected in different layers.

The second touch line 182 may be disposed in a non-emitting area other than the emission area in the display area AA, which is opened by the third organic film 143, to prevent the luminance and light transmittance of the emission area from deteriorating. The second touch line 182 is disposed to overlap the third organic film 143 in the non-emitting area in the display area AA.

The second touch line 182 may be disposed in a mesh shape in a non-emitting area of the display area AA. The inside of the mesh shape may be a rhombus or a rectangle. The emission area may correspond to the sub-pixel SP. The second touch line 182 is disposed up to an area beyond the encapsulation layer 150.

The second touch line 182 may cover the inner dam IDM in the non-display area NA and may be disposed up to an area adjacent to the outer dam ODM outside the inner dam IDM. The second touch line 182 may be connected with the connection wire 131 in a region before the bending area BA and may be connected to a touch driver (not shown) beyond the bending area BA through the connection wire 131 in the bending area BA.

The second touch line 182 is connected with the connection wire 131 in the bending area BA so as to prevent the wire from cracking due to bending. A connecting portion TP where the second touch line 182 (or the first touch line 181) connects with the connection wire 131 is between the inner dam IDM and the outer dam ODM in a cross-section view of the display device.

The connecting portion TP of the second touch line 182 and the connection wire 131 is disposed on the third insulating film 123, which may be a region from which the first organic film 141 and the second organic film 142 are simultaneously removed. For example, the second touch line 182 may be connected with the connection wiring 131 disposed on the third insulating film 123 through the contact hole of the first organic film 141 while being disposed on the first organic film 141 through the contact hole of the second organic film 142.

In an example, while the second touch line 182 is shown as being connected with the connection wire 131 in the bending area BA and extending beyond the bending area BA in the drawing, this is merely to illustrate the path of the touch signal and may be the same or similarly applicable to the first touch line 181, although not shown.

For example, the first touch line 181 may be connected to the connection wire 131 between the inner dam IDM and the outer dam ODM and connected to the touch driver (not shown) beyond the bending area BA through the connection wire 131 in the bending area BA.

The second touch line 182 may be disposed using an opaque conductive material having a low material resistivity. The second touch line 182 may be disposed as a single layer or a multilayer made of any one of molybdenum (Mo), copper (Cu), titanium (Ti), aluminum (Al) chrome (Cr), gold (Au), nickel (Ni), neodymium (Nd), tungsten (W), gold (Au), and transparent conductive oxide (TCO), or an alloy thereof.

For example, the first touch line 181 and the second touch line 182 may be a three-layer structure of titanium (Ti)/aluminum (Al)/titanium (Ti) made of a conductive metallic material.

The touch member 180 further includes the connection wire 131 that is connected with the first touch line 181 or the second touch line 182 and is extended to the bending area BA.

The connecting portion TP where the first touch line 181 or the second touch line 182 is connected to the connection wiring 131 is disposed on the inside of the bending area BA adjacent to the bending area BA to reduce the occurrence of cracks when the display panel 110 is bent. That is, the connecting portion TP is non-overlapping with the bending area BA. The connecting portion TP may be disposed between the inner dam IDM and the outer dam ODM.

The connection wire 131 is disposed to extend outwardly from the bending area BA so as to be connected with the touch driver (not shown) that is connected in the pad area PA of the non-display area NA to allow the first touch line 181 or the second touch line 182 to be connected with the touch driver (not shown) beyond the bending area BA.

The connection wire 131 disposed in the non-display area NA may include the same material as the material of one electrode constituting the transistor TR of the display area AA or may be disposed on the same layer as the transistor TR.

The touch planarization film 184 is disposed on the first touch line 181 and the second touch line 182. The touch planarization film 184 may cover steps or curves of the structures disposed under the touch planarization film 184, including the first touch line 181 and the second touch line 182, and provide a planarized upper surface.

The touch planarization film 184 may be disposed in the area where the first touch line 181 or the second touch line 182 is disposed. Specifically, the touch planarization film 184 may be disposed in front of the display area AA to cover the inner dam IDM in the non-display area NA and to expose the organic film disposed under the touch planarization film 184 in the bending area BA.

For example, the touch planarization film 184 may be disposed such that the second organic film 142 of the bending area BA in the non-displayed area NA is exposed. The touch planarization film 184 may be disposed to overlap the connecting portion TP at the inside of the bending area BA in the non-display area NA adjacent to the bending area BA, and not to overlap the outer dam ODM.

The touch planarization film 184 may cover the electrodes disposed under the touch planarization film 184, such as the first touch line 181 and the second touch line 182, to prevent moisture and oxygen from flowing inward and to prevent corrosion of the first touch line 181 and the second touch line 182.

The touch planarization film 184 may include an organic material. The organic material constituting the touch planarization film 184 may include, for example, a polymer such as silicon oxycarbon (SiOCz) epoxy, polyimide, polyethylene, or acrylate-based polymer.

A protective film 186 may be disposed on the touch planarization film 184. The protective film 186 may additionally planarize an area that is not partially planarized by the touch planarization film 184.

The protective film 186 is disposed on the front surface of the display area AA to cover the touch planarization film 184. The protective film 186 may be disposed to cover the first touch line 181 and the second touch line 182, which are disposed in the display area AA and the non-display area NA. The protective film 186 may cover the touch planarization film 184 covering the inner dam IDM in the non-display area NA, and may be disposed to expose an organic film disposed under the touch planarization film 184 in the bending area BA.

For example, the protective film 186 may be disposed to expose the portion of the third organic film 143 that is in the bending area BA. The protective film 186 may be disposed to overlap the connecting portion TP inside the bending area BA in the non-display area NA adjacent to the bending area BA and to overlap at least a portion of the outer dam ODM.

The protective film 186 may additionally block moisture and oxygen that may be introduced from the outside of the display device 100.

The protective film 186 may include an organic material. The organic material may be, for example, a polymer such as silicon oxycarbon (SiOCz) epoxy, polyimide, polyethylene, or acrylate-based polymer. The protective film 186 may have a thermosetting property or photocurable property that is cured by heat or light. For example, the protective film 186 may have an ultraviolet curable property that include a photoinitiator that initiates a polymerization reaction upon receiving ultraviolet rays.

The protective film 186 may be disposed on the panel 30 in a variety of ways, such as inkjet coating or slit coating. For example, the protective film 186 may be disposed by spraying or dropping a liquid organic material onto the display area AA using an inkjet device or a nozzle coating device on the substrate 111 on which the touch planarization film 184 is disposed. As a spray nozzle moves over an area to be applied (or as the spray nozzle is stationary and a target moves), the protective film 186 made of an organic material in a fluid state may be disposed in the area to be applied.

The protective film 186 may be made of an organic material and may be in a high-density liquid-like state until cured, allowing it to spread toward the bending area BA in the non-displayed area NA. The outer dam ODM is disposed adjacent to the bending area BA in the non-displayed area NA to control the flow of the protective film 186 that may spread toward the bending area BA.

The outer dam ODM is disposed on the inside of the bending area BA to be adjacent to the boundary of the bending area (BA) on the outside of the inner dam IDM. The outer dam ODM may be disposed between the inner dam IDM and the bending area BA.

The outer dam ODM is disposed to be in contact with the protective film 186 of the touch member 180 in the non-display area NA to control the flow of the protective film 186. The protective film 186 of the touch member 180 may be in contact with the inside of the outer dam ODM that prevents the protective film 186 from flowing to the bending area BA. The outer dam ODM may surround the inner dam IDM (see FIG. 3) and may be disposed to be in contact with the protective film 186 of the non-display area NA.

The outer dam ODM may be disposed on the third organic film 143 to be adjacent to the boundary of the bending area BA. Meanwhile, the third organic film 143 in the non-display area NA may be disposed on the second organic film 142 of the bending area BA so as to overlap the bending area BA.

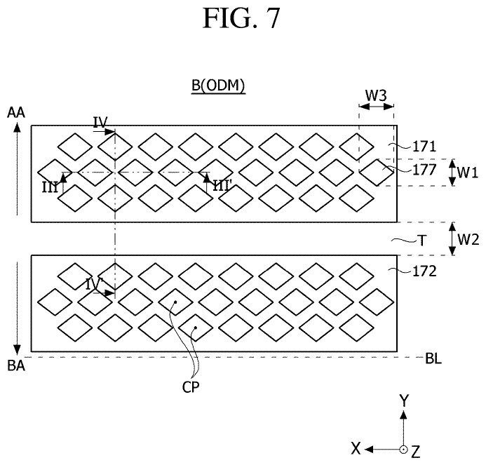

Referring to FIGS. 5 and 7, the outer dam ODM is spaced apart from the inner dam IDM and is disposed to be adjacent to the bending area BA. The outer dam ODM may be disposed to overlap a coating layer 192 disposed over the bending area BA. In one embodiment, a plurality of outer dams ODM may be disposed. The plurality of outer dams ODM may be spaced apart from each other and may be disposed along the perimeter of the non-display area NA.

The plurality of outer dams ODM may include a first outer dam 171 and a second outer dam 172. The first outer dam 171 and the second outer dam 172 are spaced apart from each other, and the second outer dam 172 may be disposed between the first outer dam 171 and the bending area BA. A trench T may be provided in a space separated between the first outer dam 171 and the second outer dam 172.

The trench T, which is disposed adjacent to the bending area BA, may be disposed in a direction parallel to a bending line BL or a direction along the bending line BL. The trench T between the first outer dam ODM and the second outer dam ODM may be disposed on four faces (e.g., a plurality of sides) of the non-display area NA in such a way that it wraps around the perimeter of the display area AA in a plan view of the display device. A portion of the third organic film 143 may be exposed in the trench T.

Even if the protective film 186 is not completely blocked by the first outer dam 171 and partially overflows over the first outer dam 171, further overflow of the protective film 186 may be blocked by the second outer dam 172, thereby trapping the protective film 186 within the trench T.

The outer dam ODM may have a plurality of holes 177 therein. In one embodiment the holes 177 extend through an entire thickness of the outer dam ODM. Each of the outer dams ODM according to one embodiment has a number of holes 177 therein. A number of the holes 177 are spaced apart from each other and disposed inside the outer dam ODM. Since the outer dam ODM is disposed along the perimeter of the display area AA, a number of holes 177 disposed inside the outer dam ODM may also be disposed along the perimeter of the display area AA.

The outer dams ODM according to the present specification may serve as bumps for controlling the flow of the protective film 186 of the touch member 180, e.g., a number of holes 177 may be provided inside the outer dam ODM to act as if a number of bumps are disposed between the hole 177 and the hole 177 on the main body of the outer dam ODM. In addition, it is possible to increase the surface contact area through a number of holes 177 in the outer dam ODM, thereby increasing the surface resistivity.

Accordingly, the outer dam ODM having a number of holes 177 according to the present specification may not only reduce the flow rate of the protective film 186 of the touch member 180 but also contain the protective film 186 to overflow from the outer dam ODM, thereby further improving the effect of preventing the protective film 186 of the touch member 180 from spreading. Accordingly, the display device 100 according to the present specification may prevent deformation of the display device.

The outer dam ODM is disposed in an embossed, raised pattern relative to the substrate 111. Chemical materials used during a process of patterning the outer dam ODM may leave a residue of relatively large amounts around the outer dam ODM. The residual chemical materials may denature the organic films 140 (141, 142, and 143) under the outer dam ODM, and the denatured organic film 140 adjacent to the bending area BA may have a higher probability of cracking.

For example, the portion of the third organic film 143 exposed in the trench T between the first outer dam 171 and the second outer dam 172 may be denatured into the residual chemical materials, causing the trench T to become a crack path and the crack to propagate through the trench T.

However, the outer dam ODM according to the present specification may have a number of holes 177 therein to disperse the crack path by means of the holes 177 and prevent the crack from spreading, instead of concentrating the crack paths toward the periphery of the outer dam ODM, such as the trench T. Therefore, the display device 100 according to the present specification may improve reliability.

In one embodiment, the plurality of holes 177 are arranged in a plurality of rows of holes in a direction that is parallel to a bending line BL of the bending area BA. Among a number of the holes 177, the center points CP of the holes 177 disposed in any row in a direction parallel to the bending line BL of the bending area BA and the center points CP of the holes 177 disposed in the next or previous row in the number of the holes 177 are disposed to be deviated from each other in a direction perpendicular to the bending line BL. That is, a center point CP of a first hole in a first row from the plurality of rows of holes is not aligned with a center point CP of a second hole that is in a second row from the plurality of rows of holes in a direction perpendicular to the bending line BL. The imaginary line connecting the center points CP of a number of the holes 177 may have a zigzag shape. A center point CP is a point where the center of a hole 177 meets with respect to an imaginary line oriented parallel to the bending line BL.

When a number of the holes 177 are disposed in a zigzag manner within the outer dam ODM, the bending stress that may be applied to the outer dam ODM disposed adjacent to the bending area BA and the third organic film 143 disposed in the bending line BL may be dispersed rather than concentrated in one area, thereby reducing the bending stress on the organic film 140 adjacent to the bending area BA.

Each of the holes 177 has a width W1 in a direction perpendicular to the trench T and a width W3 in a direction parallel to the trench T or parallel to the bending line BL. The width W1 of the holes 177 in a direction perpendicular to the trench T may be less than the width W2 of the trench T. The width W3 of the holes 177 in a direction parallel to the bending line BL may be larger than the width W1 of the holes 177 in a direction perpendicular to the trench T or perpendicular to the bending line BL.

To satisfy this, in one embodiment, the holes 177 may have a rhombus or diamond shape, as shown in FIG. 7. The outer dam ODM may have a mesh shape therein.

If the width W3 of the holes 177 in the direction parallel to the bending line BL is greater than the width W1 of the holes 177 in the direction perpendicular to the bending line BL, the bending stress applied in the direction of the bending line BL may be transferred to a number of the holes 177 in the outer dam ODM disposed adjacent to the bending area BA. The bending stress transferred to a number of the holes 177 may not be concentrated in one location, and may be distributed in a wide width direction of the holes 177 perpendicular to the bending line BL.

The display device 100 according to the present specification may distribute the bending stress to prevent the concentration of the bending stress that may be applied around the bending area BA and the occurrence of the cracking of the surrounding wires or films that may be caused by the stress.

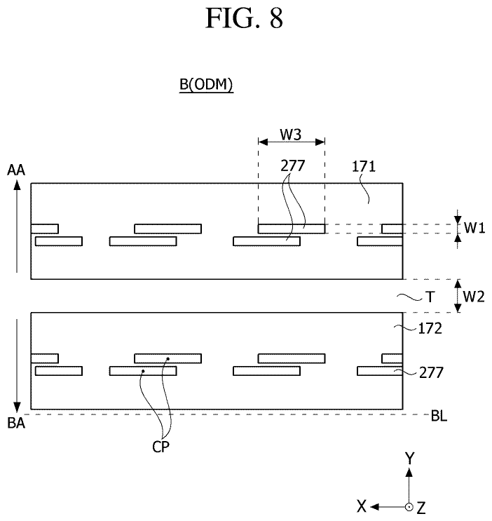

In another embodiment, as shown in FIG. 8, the holes 277 may have a rectangular shape with long sides in a direction parallel to the bending line BL.

The components having the same reference numerals described with reference to FIGS. 1 to 7 and 9 to 10 may be equally applied or implemented in the embodiment of FIG. 8, or may be applied or implemented in combination with or combined with the embodiments described with reference to FIGS. 1 to 7 and 9 to 10, and a description of components having the same reference numerals will be omitted.

Among a number of the holes 277, the center points CP of the holes 277 disposed in any row in a direction parallel to the bending line BL of the bending area BA and the center points CP of the holes 277 disposed in the next or previous row in the number of the holes 177 are disposed to be deviated from each other in a direction perpendicular to the bending line BL. The width W3 of the holes 277 in a direction parallel to the bending line BL may be larger than the width W1 of the holes 277 in a direction perpendicular to the trench T or perpendicular to the bending line BL.

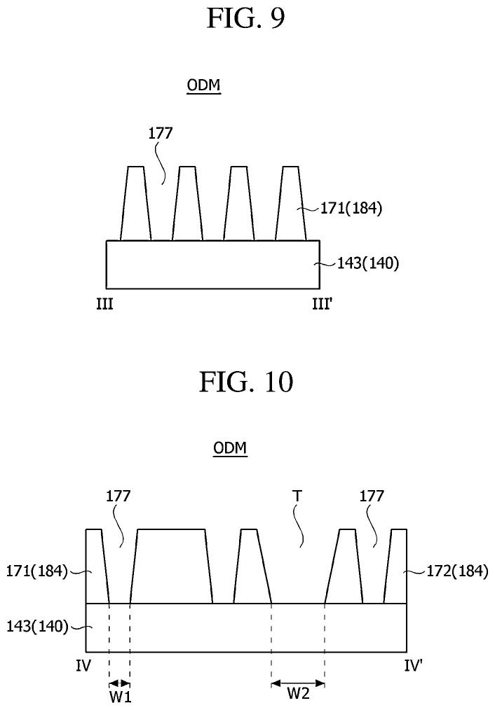

As shown in FIGS. 9 and 10, the holes 177 may penetrate inside the outer dam ODM to expose a layer disposed under the outer dam ODM. A portion of the third organic film 143 may be exposed through the holes 177. The depth of the holes 177 may be the same as the depth of the trench T.

The outer dam ODM may include the same material as the constituent material of the touch planarization film 184 or may be disposed on the same layer as the touch planarization film 184. The outer dam ODM and the touch planarization film 184 may include the same organic material. The outer dam ODM may include a polymer such as epoxy, acrylate, or polyethylene.

On the other hand, the inner dam IDM may include the same material or may be disposed in the same layer as the organic film 140 disposed in the display area AA.

Additional process steps may be reduced when the inner dam IDM and the outer dam ODM disposed in the non-display area NA are made of the same material or are disposed in the same layer as the film disposed in the display area AA. Therefore, the display device 100 according to the present specification may reduce the greenhouse gases that may be generated by the manufacturing process by optimizing the process, thereby implementing enabling ESG (Environment/Social/Governance).

The outer dam ODM and the third organic film 143 exposed through the holes 177 and 277 in the outer dam ODM may include different materials. The outer dam ODM and the third organic film 143 having different materials may have different surface tensions, and the outer dam ODM may increase the surface tension difference therein. Therefore, when the protective film 186 of the touch member 180 flows toward the bending area BA, the outer dam ODM, which has the different surface tensions therein, may more effectively control the overflow of the protective film 186.

The display device 100 according to the present specification may improve the durability of the display panel 110 and reduce the occurrence of deformation or defects of the display device 100 by disposing a number of holes 177 and 277 in the outer dam ODM so as to increase the resistance of the surface energy barrier against the direction in which the protective film 186 of the touch member 180 spreads.

Referring again to FIG. 6, the optical member 90 is disposed on the protective film 186 of the touch member 180. The optical member 90 may be referred to as a polarizer. The optical member 90 may be disposed to overlap the display area AA of the display panel 110 and to correspond to the front surface of the non-display area AA. The optical member 90 may be disposed between the cover member 20 and the display panel 110, as shown in FIG. 2. The optical member 90 may include an adhesive layer (not shown) and may be attached to the rear surface of the cover member 20 by means of the adhesive layer disposed on the upper surface thereof.

The optical member 90 may be disposed on the display panel 110 to block the light emitting of the light which is incident from the outside and then reflected from the electrodes and wires disposed on the panel 30 and the touch lines disposed on the touch member 180.

The optical member 90 may be disposed to overlap at least a portion of the non-display area NA to cover the first touch line 181 and the second touch line 182, as shown in FIG. 6.

The optical member 90 is disposed on the protective film 186 of the touch member 180 in the non-display area NA. The optical member 90 may be disposed up to the inside region of the bending area BA of the non-display area NA. The optical member 90 may be disposed on the protective film 186 in the non-display area NA and may be disposed along the shape of the upper surface of the protective film 186. The outer dam ODM may be disposed on the outside of the periphery of the optical member 90. The optical member 90 may be disposed to extend to a position where the protective film 186 begins to slope downward (e.g., a relatively flat section of the protective film 186) by controlling the flow of the protective film 186 by the outer dam ODM. Because the protective film 186 may be prevented from flowing by the outer dam ODM, the edge of the optical member 90 may not be inclined or wrinkled along the protective film 186.

As described above, the flow rate of the protective film 186 is reduced by the outer dam ODM having a number of the holes 177 and 277, and thus the protective film 186 is trapped inside or within the outer dam ODM.

If the protective film 186 flows into the bending area BA so that the protective film 186 does not sufficiently support the optical member 90, the optical member 90 may be arranged on the protective film 186 with a slope or wrinkle formed corresponding to the upper surface of the protective film 186.

However, the display device 100 according to the present specification may be controlled by an outer dam ODM having a number of the holes 177 and 277 to ensure that the protective film 186 sufficiently supports the optical member 90, thereby preventing the outer portion of the optical member 90 from being inclined or wrinkled.

A waviness phenomenon, such as the outer portion of the optical member 90 being wrinkled in the non-display area NA, may be visible to the user to deteriorate the display quality of the display device 100.

The display device 100 according to the present specification may improve the poor waviness of the periphery of the optical member 90 and may ensure that the display quality of the display device 100 is not deteriorated.

An edge of the optical member 90 in the non-display area NA may be in contact with the coating layer 192. The contact portion of the optical member 90 and the coating layer 192 may be located between the inner dam IDM and the outer dam ODM. The coating layer 192 is disposed on the bending area BA to prevent bending stresses generated in the bending area BA from being transferred to the periphery of the bending area BA.

The coating layer 192 may be at least partially in contact with the protective film 186 of the touch member 180. The coating layer 192 may be disposed at the boundary of the bending area BA such that it is in contact with the upper surface of the outer dam ODM.

In one embodiment, when a plurality of outer dams ODM are arranged, the coating layer 192 may be arranged to overlap the first outer dam 171 and the second outer dam 172, and to fill the space between the first outer dam 171 and the second outer dam 172. The coating layer 192 may be filled within the trench T between the first outer dam 171 and the second outer dam 172.

The coating layer 192 may be in contact with the optical member 90 at a location in the non-display area NA that is between the inner dam IDM and the outer dam ODM in a cross-section view of the display device. The contact portion of the optical member 90 and the coating layer 192 may overlap the touch planarization film 184 and the protective film 186.

A back plate 31 may be disposed on the rear surface of the substrate 111 as illustrated in FIG. 6. The back plate 31 allows the substrate 111 to remain flat and supports the substrate 111. The back plate 31 may be attached to the rear surface of the substrate 111 by means of an adhesive (not shown) or the like. The back plate 31 is arranged to overlap the display area AA and not to overlap the bending area BA.

The back plate 31 may be disposed with a certain strength and thickness to complement the rigidity of the substrate 111. The back plate 31 may be made of a rigid plastic thin film. For example, the back plate 31 may include one of polyethylene terephthalate (PET), polyimide (PI), and polyethylene naphthalate (PEN).

The display device 100 according to the present specification may improve display quality by reducing waviness defects of the optical member by an outer dam ODM having a number of holes therein.

The display device 100 according to the present specification may have an outer dam ODM having a number of holes therein, which may reduce the occurrence of cracks due to bending stress, thereby improving reliability.

The present specification may reduce the occurrence of relative defects by improving the reliability of the display device 100, thereby reducing the use of harmful production materials or regulatory substances for producing the display device 100, which may be advantageous for recycling and may approach the realization of the environmentally friendly display device 100.

Although the above has been described with reference to the embodiments, these are only examples and do not limit the present invention, and the present specification described above is not limited to the above-described embodiments and the accompanying drawings, and the features, structures, effects, and the like exemplified in each embodiment may be implemented by combining or modifying them. Accordingly, the contents relating to such combinations and modifications should be construed as being included within the scope of the present invention.

[Description of reference numerals]

| | |
|---|---|
| 10: Bottom member | 20: Cover member |
| 30: Panel | 90: Optical member |
| 100: Display device | 110: Display panel |
| 111: Substrate | 120: Insulating film |
| 121: First insulating film | 122: Second insulating film |
| 123: Third insulating film | 131: Connection wire |
| 135: Light-emitting element | 140: Organic film |
| 141: First organic film | 142: Second organic film |
| 143: Third Organic Film | 150: Encapsulation layer |
| 151: First encapsulation layer | 152: Second encapsulation film |
| 154: Organic encapsulation layer | 171: First outer dam |
| 172: Second outer dam | 177, 277: Halls |
| 180: Touch member | 181: First touch line |
| 182: Second touch line | 183: Touch insulating film |
| 184: Touch planarization film | 186: Protective film |
| 192: Coating layer | BA: Bending area |
| BL: Bending line | IDM: Inner dam |
| ODM: Outer dam | T: Trench |

What is claimed is:

1. A display device comprising:
a substrate including a display area and a non-display area having a bending area;
an encapsulation layer on the display area and the non-display area;
an inner dam that is in contact with the encapsulation layer in the non-display area;
a touch member disposed on the encapsulation layer and the inner dam and including a protective film; and
an outer dam that is in contact with the protective film of the touch member in the non-display area.

2. The display device of claim 1, wherein the outer dam is adjacent to a boundary of the bending area such that the outer dam is between the inner dam and the boundary in a cross-sectional view of the display device.

3. The display device of claim 1, wherein the outer dam surrounds the inner dam in a plan view of the display device and is in contact with a plurality of sides of the protective film in the non-display area.

4. The display device of claim 1, wherein the outer dam comprises:
a first outer dam;
a second outer dam spaced apart from the first outer dam; and
a trench between the first outer dam and the second outer dam,
wherein the trench is on a plurality of sides of the non-display area that surround the display area in a plan view of the display device.

5. The display device of claim 4, wherein the outer dam comprises a plurality of holes, and a width of the plurality of holes in a direction perpendicular to a direction of the trench is less than a width of the trench.

6. The display device of claim 5, wherein a depth of the plurality of holes is equal to a depth of the trench.

7. The display device of claim 1, wherein the outer dam comprises a plurality of holes that expose a layer under the outer dam.

8. The display device of claim 7, wherein the plurality of holes are arranged in a plurality of rows of holes in a direction that is parallel to a bending line of the bending area, and a center point of a first hole in a first row from the plurality of rows of holes is not aligned with a center point of a second hole that is in a second row from the plurality of rows of holes in a direction perpendicular to the bending line.

9. The display device of claim 7, wherein the bending area has a bending line at which the substrate is bent, and a width of a hole from the plurality of holes in a direction parallel to the bending line is greater than a width of the hole in a direction perpendicular to the bending line.

10. The display device of claim 1, further comprising:
a coating layer on the bending area,
wherein the coating layer contacts a portion of the protective film in the non-display area and an upper surface of the outer dam is in contact with the coating layer.

11. The display device of claim 10, wherein the outer dam comprises:
a first outer dam; and
a second outer dam that is spaced apart from the first outer dam,
wherein the coating layer fills in a space between the first outer dam and the second outer dam.

12. The display device of claim 1, wherein the touch member further comprises:
a first touch line on the encapsulation layer in the display area and the non-display area;
a touch insulating film on the first touch line in the display area and the non-display area;
a second touch line on the touch insulating film in the display area and the non-display area; and
a touch planarization film on the second touch line in the display area and the non-display area,
wherein the protective film is on the touch planarization film.

13. The display device of claim 12, wherein a material of the outer dam is a same as a material of the touch planarization film of the touch member.

14. The display device of claim 12, further comprising:
a connection line connected with the first touch line or the second touch line in the non-display area, the connection line extending to the bending area,
wherein a connecting portion where the first touch line or the second touch line is connected with the connection line is located between the inner dam and the outer dam in a cross-section view of the display device.

15. The display device of claim 1, wherein the encapsulation layer includes:
a first encapsulation layer having an inorganic material, the first encapsulation layer in the display area and the non-display area;
an organic encapsulation layer on the first encapsulation layer in the display area and the non-display area, the organic encapsulation layer having an organic material; and
a second encapsulation layer on the organic encapsulation layer in the display area and the non-display area,
wherein the encapsulation layer overlaps the inner dam and is non-overlapping with the outer dam, and the protective film of the touch member overlaps the inner dam and overlaps at least a portion of the outer dam.

16. The display device of claim 15, wherein the organic encapsulation layer contacts the inner dam without contacting the outer dam.

17. The display device of claim 1, further comprising:
an optical member on the protective film of the touch member in the display area and the non-display area; and
a coating layer on the bending area and on the outer dam in the non-display area,
wherein the optical member and the coating layer are in contact with each other at a location between the inner dam and the outer dam in a cross-section view of the display device.

18. The display device of claim 12, wherein a material of the inner dam is a same as a material of a planarization film that is in the display area and under the encapsulation layer, and the outer dam overlaps the non-display area and a material of the outer dam is a same as a material of the touch planarization film that is on the encapsulation layer.

19. The display device of claim 18, wherein the material of the outer dam and the material of the touch planarization film include a same organic material.

20. The display device of claim 1, wherein the inner dam controls a flow of the encapsulation layer, and the outer dam controls a flow of the protective film of the touch member on the encapsulation layer.
